(19) United States
(12) Patent Application Publication
(10) Pub. No.: US 2021/0178419 A1
(43) Pub. Date: Jun. 17, 2021

(54) METHOD FOR PRODUCING A PRINTED CIRCUIT BOARD PROVIDED WITH AT LEAST ONE COATING, AND COATING HEAD FOR CARRYING OUT THE METHOD

(71) Applicant: Endress+Hauser Flowtec AG, Reinach (CH)

(72) Inventors: Johannes Ruchel, Arlesheim (CH); Stefanie Berchtold, Aesch (CH); Markus Ursprung, Brunegg (CH); Daniel Kollmer, Maulburg (DE)

(21) Appl. No.: 16/758,786

(22) PCT Filed: Sep. 27, 2018
(86) PCT No.: PCT/EP2018/076292

§ 371 Date: Apr. 23, 2020

(30) Foreign Application Priority Data
Oct. 23, 2017 (DE) 10 2017 124 665.7

(51) Int. Cl. B05C 9/10; H05K 3/00; H05K 3/28; B01F 3/08; B01F 7/24; B01F 7/00; B05C 11/10; B05B 7/04; B05B 1/04

(52) U.S. Cl. CPC B05C 9/10; H05K 3/0091; H05K 3/284; B01F 3/0853; B01F 7/24; B01F 7/00416; B01F 2215/0477; B05B 7/0408; B05B 1/044; H05K 2203/0126; H05K 2203/1366; B01F 2215/0039; B01F 2215/0481; B05C 11/10

(57) ABSTRACT

The present disclosure includes a method for producing a printed circuit board having at least one coating includes mixing a first component with a second component of a two component coating system to form a coating mixture by means of a dynamic mixer or by means of a static-dynamic mixer. The method also includes supplying the coating mixture to an output unit, and coating the printed circuit board by outputting the coating mixture using the output unit onto the printed circuit board. The output unit is moved automatically in at least one, two, or three dimensions relative to the printed circuit board. The mixer is connected with the output unit in such a manner that it is moved together with the output unit relative to the printed circuit board. The present disclosure also includes a coating head for performing the method.

The present invention relates to a method for producing a printed circuit board provided with at least one coating and a coating head therefor. Protective coatings for printed circuit boards are known per se. They protect the printed circuit boards against moisture, and mechanical loading, improve heat removal and enable in the sense of explosion protection shorter distances between circuit elements.

Solvent containing coating systems are used for this purpose. Forming an alternative to solvent containing systems are two component systems, for example, systems based on polyurethanes, epoxide resins or silicones. In the case of two component systems, however, a sufficient mixing is absolutely required, in order to achieve an adequate quality of the coating layer. On the other hand, with the mixing of the components their reaction with one another begins, which occurs faster as the degree of mixing increases. As the reaction occurs, the viscosity of the mixture begins to increase and this creates tight limits for its workability. For example, a coating dispensed with a curtain nozzle is only sensible with viscosities up to 100 μPaS. Suitable methods for coating of printed circuit boards with a two component system having a sufficiently homogeneous coating layer have not been previously available.

It is, consequently, an object of the present invention to provide a method and a corresponding a coating head for performing the method.

The object is achieved by the method as defined in independent claim 1 and the coating head as defined in independent claim 14.

The method of the invention for producing a printed circuit board provided with at least one coating includes at least steps as follows:

mixing at least a first component with a second component of an at least two component coating system to form a coating mixture by means of a dynamic mixer and/or by means of a static-dynamic mixer.

supplying the coating mixture to an output unit; and

coating the printed circuit board by outputting the coating mixture by means of the output unit onto the printed circuit board;

wherein the output unit during the coating of the coating mixture is moved automatically in at least one dimension, especially in two or three dimensions, relative to the printed circuit board;

wherein the dynamic mixer is connected in such a manner with the output unit that it is automatically moved together with the output unit relative to the printed circuit board. In most cases, a movement in two dimensions, for example, the X and Y dimensions in parallel with printed circuit board, especially in a raster, is sufficient, in order to perform the coating. To the extent that especially large electronic chips or other electrical or electronic devices are located on the printed circuit board, a variation of the distance to the printed circuit board surface, i.e. the Z dimension, can be required.

In the case of a dynamic mixer, the mixing action is achieved by movement of a mixer body, for example, rotation of a rotor. In the case of a static mixer, the mixing is achieved, in contrast, by flow around a fixed mixer body, for example, ribbon blades, or screws, with sections of alternating helicity. In the case of static-dynamic mixers, mixer bodies, which are to a certain degree suitable for static mixers, are moved supplementally, in order therewith to improve the mixing action. Both static-dynamic mixers as well as also dynamic mixers require a motor for driving the mixer body.

In a further development of the invention, the mixer includes a motor and a rotor, wherein the motor drives the rotor such that the rotor rotates with a rotational speed of not less than 500 RPM, especially not less than 1000 RPM, for example, not less than 2000 RPM and even not less than 3000 RPM. The use of a mixer with these properties enables a sufficiently homogeneous mixing of the components in a short time, so that a coating can be obtained, which, on the one hand, is homogeneous after the hardening and, on the other hand, has while being output onto the printed circuit board still a viscosity under 200 μPaS, especially no more than 100 μPaS. These conditions are achieved, even though the coating system is preferably solvent free.

In another development of the invention, the output unit outputs the coating mixture with a cross sectional area, which amounts to no more than 1%, for example, no more than 0.3%, especially no more than 0.1% A of the area of the printed circuit board.

In another development of the invention, the output unit outputs the coating mixture with a cross sectional area, whose longest dimension amounts to no more than a third, for example, no more than a sixth and especially no more than an eighth of the square root of the area of the printed circuit board.

In this way, the spatial resolution of the coating application is sufficient that regions of a printed circuit board, which are not to be coated with the coating mixture, can be selectively avoided. This is associated with the disadvantage that the output unit must undergo multiple direction changes relative to the printed circuit board, this being accompanied by considerable accelerations when coupled with short working times.

In another development of the invention, the mixer including the motor and the output unit, as well as, in given cases, other components, such as valves and their valve drives, which are moved together relative to the printed circuit board, have a total mass of no more than 1.5 kg, especially no more than 1 kg.

These mass limits assure that the acceleration forces during the coating remain small, so that shaking of the printed circuit boards can be avoided with little effort.

In another development of the invention, the rotor includes a ribbon blade, or screw, for mixing, especially a ribbon blade, or screw, with sections of alternating helicity.

In another development of the invention, the rotor includes mixing elements and rotates relative to a stator.

In another development of the invention, the mixer includes an essentially cylindrical mixing chamber, in which the rotor is arranged, wherein the mixing chamber has an inner diameter, which amounts to not less than 4% and no more than 20% of the length of the rotor, wherein the mixer is a static-dynamic mixer.

In another development of the invention, the first component and the second component are fed to the mixer from supply containers via flexible lines. This has the advantage that the supply containers do not need to be accelerated with the mixer relative to the printed circuit board.

In another development of the invention, the residence time of the components in the mixer extending to termination of the dynamic mixing procedure amounts, on average, to no more than 100 sec, for example, no more than 40 sec, especially no more than 20 sec.

In another development of the invention, the mixer has a mixing volume extending from the location of the entrance of the components into the mixer to the location of the termination of the dynamic mixing procedure and filled with the components, or the coating mixture, as the case may be; and a output opening of the output unit, where the coating mixture is output, is spaced no more than five times, especially no more than twice, the third root of the mixing volume from the location of the termination of the dynamic mixing procedure.

In another development of the invention, the mixer has a mixing volume extending from the location of the entrance of the components into the mixer to the location of the termination of the dynamic mixing procedure and filled with the components, or the coating mixture, as the case may be; wherein the volume filled with the coating mixture between the output opening of the output unit, where the coating mixture is output, and the location of the termination of the dynamic mixing procedure amounts to no more than four times, especially no more than twice, the mixing volume.

The described, compact construction of the apparatus contributes likewise to keeping the residence time of the coating mixture after completion of the mixing process sufficiently small that the coating mixture is still output with sufficiently low viscosity.

In another development, the output unit comprises a jet valve, a dispenser, or a curtain nozzle.

In another development of the invention, the output unit and/or the mixer are temperature controlled, especially heatable.

A coating head of the invention for coating printed circuit boards, especially according to the method of the invention, includes a dynamic or static-dynamic mixer having at least two component inlets; and an output unit, which is connected in such a manner with the mixer that the mixer upon coating can be moved together with the output unit over a printed circuit board to be coated, so that the mixer experiences the same accelerations as the output unit, wherein the mixer has a motor and a rotor, wherein the motor drives the rotor such that the rotor rotates with a rotational speed of not less than 500 RPM, especially not less than 1000 RPM, for example, not less than 2000 RPM and even not less than 3000 RPM.

In another development of the invention, the coating head has, including other components, which are connected with the mixer, so that they must be moved together with the mixer during the coating, a mass of no more than 1.5 kg, especially no more than 1 kg. Such additional components can comprise, for example, valves, especially needle valves, and their actuators, for example, pneumatic actuators.

The invention will now be explained in greater detail based on an example of an embodiment shown in the drawing. The figures of the drawing show as follows:

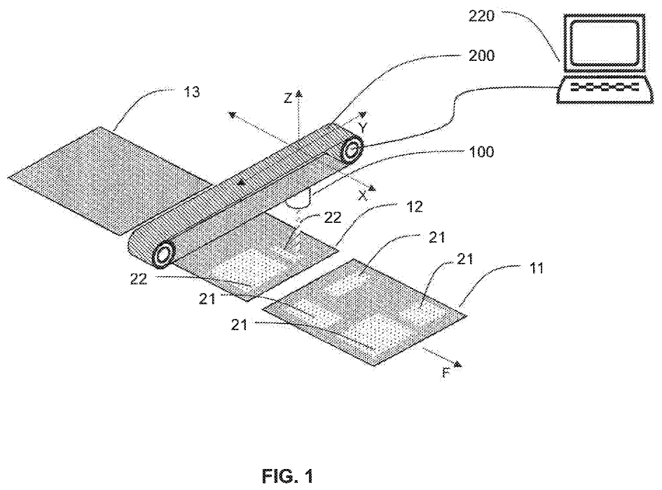

FIG. 1 a schematic view of an arrangement for coating printed circuit boards; and

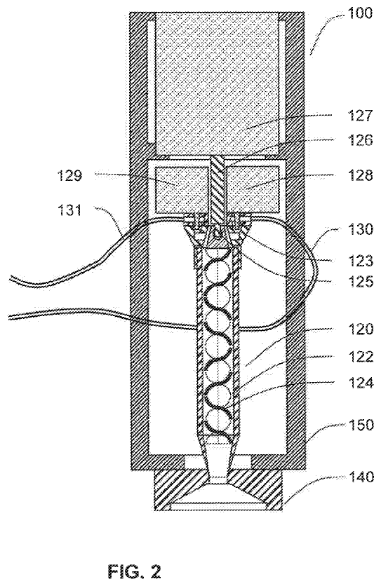

FIG. 2 a schematic view of an example of an embodiment of a coating head for performing the method of the invention.

As shown in FIG. 1, printed circuit boards 11, 12, 13 are moved by means of a conveyor belt (not shown) in a transport direction past a coating station. The first printed circuit board 11 has already been coated in surface segments 21, while the second printed circuit board 12 is in the process of being coated. A first surface segment 22 is done, while a second surface segment is just being coated. During the coat application, the printed circuit boards are not moved.

The coating occurs by means of a coating head 100 of the invention, which is moved in an X-Y-plane in parallel with printed circuit board by means of a positioning system 200 driven with stepper motors. The positioning system 200 is here only shown with one degree of freedom in the Y dimension. Further details for other degrees of freedom are within the skill of the art.

The coating head 100 and the positioning system are controlled by a computer unit 220.

The applied coating system is a solvent free, two component system, especially a polyurethane system, wherein the first component comprises an isocyanate and the second component a bifunctional alcohol, i.e. an alcohol with two hydroxyl groups. Likewise suitable are epoxide resin systems with an epoxide resin and a hardener as components, or two component silicone systems, wherein one component contains a catalyst.

The example of an embodiment of a coating head 100 of the invention schematically illustrated in FIG. 2 comprises a mixer 120, which here is a static-dynamic ribbon blade mixer, or screw mixer. These types of mixers comprise, conically narrowing at an outlet end, a mixer cylinder 122, which has in its interior a mixing chamber, in which a ribbon blade mixer 124, or mixer screw, with segments of alternating helicity is located. Such mixers are obtainable, for example, from the firm, Nordson. Placed on the mixer cylinder is a chamber head 123. The mixer cylinder 122 and the mixer ribbon blade, or screw, 124 can be embodied as consumables, which after some hours of operation are replaced. The mixer ribbon blade, or screw, 124 includes on its upper end away from the outlet end of the mixer cylinder, a seat 125 for a complementary engagement means to the bottom part of a drive shaft 126 of an electric motor 127, with which the mixer ribbon blade, or screw, is driven with a rotational speed of, for example, 4500 to 5000 RPM. In order to enable a coupling between the drive shaft 126 and the mixer ribbon blade, or screw, 124, the mixer cylinder head 123 includes a central axial bore, into which one or both of the rotating components 124, 126 protrude.

The mixer cylinder head 123 additionally includes connections for supply lines 130, 131, through which the two components of the coating system are fed. The supply can be controlled with needle valve blocks 128, 129, which are arranged on the mixer cylinder head 123. The supply lines 130, 131 are connected to supply containers (not shown), from which the components are supplied via pumps, especially toothed-belt pumps or other dosing, or metering, pumps. The supply lines 130, 131 are sufficiently long that the coating head 100 can be moved during the coating over the printed circuit boards without degrading the process and without necessitating movement of the supply containers.

Arranged on the lower end of the coating head is an output apparatus, here a curtain nozzle 140 with an output width equaling that of the coating curtain, for instance, 8 mm. Between mixer 120 and curtain nozzle, a supplemental valve (not shown) can optionally be provided, in order to implement the coating output with shorter control times.

The components of the coating head 100 are held in a frame 150, especially a frame 150 made of a light metal. The total weight of the coating head 100 amounts to no more than 1 kg.

1-15. (canceled)

16. A method for producing a printed circuit board having at least one coating, comprising the following steps:
mixing at least a first component with a second component of an at least two component coating system to form a coating mixture using a dynamic mixer or a static-dynamic mixer;
supplying the coating mixture to an output unit; and
coating the printed circuit board by outputting the coating mixture by means of the output unit onto the printed circuit board;
wherein the output unit during the coating is moved automatically in at least one dimension relative to the printed circuit board;
wherein the mixer is connected in such a manner with the output unit that it is moved together with the output unit relative to the printed circuit board.

17. The method of claim 16, wherein the output unit outputs the coating mixture with a cross sectional area of no more than 1% of the area of the printed circuit board.

18. The method of claim 16, wherein the output unit outputs the coating mixture with a cross sectional area, whose longest dimension amounts to no more than a third of the square root of the area of the printed circuit board.

19. The method of claim 16, wherein the mixer includes a motor and a rotor, wherein the motor drives the rotor such that the rotor rotates with a rotational speed of not less than 500 RPM.

20. The method of claim 19, wherein the rotor has a mixer ribbon blade, or screw.

21. The method of claim 19, wherein rotor rotates relative to a stator.

22. The method of claim 19, wherein the mixer includes an essentially cylindrical mixing chamber in which the rotor is arranged; wherein the mixing chamber has an inner diameter, which amounts to not less than 4% and no more than 20% of a length of the rotor; and wherein the mixer is a static-dynamic mixer.

23. The method of claim 16, wherein the first component and the second component are fed to the mixer from supply containers via flexible lines.

24. The method of claim 16, wherein the residence time of the components in the mixer extending to termination of the dynamic mixing procedure amounts to no more than 100 seconds.

25. The method of claim preceding claims, wherein the mixer has a mixing volume extending from the location of the entrance of the components into the mixer to the location of the termination of the dynamic mixing procedure and filled with the components, or the coating mixture; and an output opening of the output unit, where the coating mixture is output, is spaced no more than five times the third root of the mixing volume from the location of the termination of the dynamic mixing procedure.

26. The method of claim 16, wherein the mixer has a mixing volume extending from the location of the entrance of the components into the mixer to the location of the termination of the dynamic mixing procedure and filled with the components, or the coating mixture; wherein the volume filled with the coating mixture between the output opening of the output unit, where the coating mixture is output, and the location of the termination of the dynamic mixing procedure amounts to no more than four times the mixing volume.

27. The method of claim 16, wherein the output unit comprises a jet valve, a dispenser, or a curtain nozzle.

28. The method of claim 16, wherein the output unit or the mixer are temperature controlled.

29. A coating head for coating printed circuit boards, comprising:
a dynamic or static-dynamic mixer having at least two component inlets; and an output unit, which is connected in such a manner with the mixer that the mixer upon coating can be moved together with the output unit over a printed circuit board to be coated, so that the mixer experiences the same accelerations as the output unit, wherein the mixer has a motor and a rotor, wherein the motor drives the rotor such that the rotor rotates with a rotational speed of not less than 500 RPM.

30. The coating head of claim 29, wherein the coating head has, including other components, which are connected with the mixer, so that they must be move together with the mixer during the coating, a mass of no more than 1.5 kg.
